(19) United States
(12) Patent Application Publication
(10) Pub. No.: US 2003/0111261 A1
(43) Pub. Date: Jun. 19, 2003

(54) Circuit within a circuit board

(76) Inventors: Mark S. Lopac, Cokato, MN (US); Terrill J. Schmidt, Dayton, MN (US)

Correspondence Address: ROBERT D. FISH; RUTAN & TUCKER, LLP, P.O. BOX 1950, 611 ANTON BLVD., 14TH FLOOR, COSTA MESA, CA, 92628-1950, US

(21) Appl. No.: 10/024,030

(22) Filed: Dec. 18, 2001

(51) Int. Cl. H05K 1/16

(52) U.S. Cl. 174/260

(57) ABSTRACT

A multi-layer printed wiring board comprises a first printed wiring assembly including a printed wiring board, and components mounted on a first surface of the printed wiring board, the components and first surface being covered by a layer of conformal material; and a first conductive pattern which is not part of the first printed wiring assembly, wherein the layer of conformal material is positioned between the first conductive pattern and the first printed wiring assembly. A method of forming a multi-layer printed wiring board comprises providing a first printed wiring assembly; encapsulating at least some components of the printed wiring assembly in a layer of conformal material to form an inner layer; and coupling at least one additional conductive layer to the inner layer such that the conformal layer is positioned between the at least one additional conductive layer and the printed wiring assembly.

### FIELD OF THE INVENTION

The field of the invention is circuit boards.

### BACKGROUND OF THE INVENTION

Printed circuit/wiring boards (PWBs) are known for providing a physical structure for mounting, holding, and interconnecting electronic components. PWBs generally comprise at least one non-conducting substrate upon which a conductive pattern is formed. PWBs are often classified as being single-sided, double-sided, or multi-layer with single-sided PWBs having a conductive pattern on a single exposed surface, double-sided having conductive patterns on two opposing exposed surfaces, and multi-layer PWBs having alternating conductive pattern and insulating layers. PWBs generally also comprise plated through-holes that are used to interconnect conductive patterns and/or to mount components to the PWB. Mounting of components may involve pads rather than through holes. The term printed wiring assembly (PWA) is sometimes used to refer to a PWB having electronic components mounted on it. Placing components on a PWB is sometimes referred to as “populating” the PWB. Thus a PWA may alternatively be referred to as a populated PWB.

The number of components in a PWA is often constrained by the surface area available on the PWB. Thus, for a design in which the PWB cannot be larger than 1 square inch, there is only 1 or 2 square inches (depending on whether components are mounted on one or two sides of the PWB) of surface area on which components can be mounted. Limited surface area constraints may have a strong negative impact on possible PWB designs.

In some instances, components are formed as part of the PWB. As an example, a capacitor may be formed in a conductive layer of the PWB through the use of one or two conductive patterns by positioning two portions of the pattern(s) adjacent to each other without interconnecting them. However, the formation of components as part of the PWB is often a limited solution, possibly in part because of the added expense in creating the PWB and/or limitations on the types of components that can be formed as part of the PWB.

Thus, there is a continuing need for methods and devices that help circumvent PWB surface area design constraints, that are cost effective, and that are not severely limited in the types of components that can be used.

### SUMMARY OF THE INVENTION

The present invention is directed a multi-layer printed wiring board that comprises a first printed wiring assembly including a printed wiring board, and components mounted on a first surface of the printed wiring board, the components and first surface being covered by a layer of conformal material; and a first conductive pattern which is not part of the first printed wiring assembly, wherein the layer of conformal material is positioned between the first conductive pattern and the first printed wiring assembly. A method of forming a multi-layer printed wiring board comprises providing a first printed wiring assembly; encapsulating at least some components of the printed wiring assembly in a layer of conformal material to form an inner layer; and coupling at least one additional conductive layer to the inner layer such that the conformal layer is positioned between the at least one additional conductive layer and the printed wiring assembly.

It is contemplated that the methods and devices disclosed herein will be (a) advantageous in increasing the number of components that can be used in the design of a circuit board by providing additional surface area for attachment of electrical components; (b) will improve the electrical shielding of components on circuit boards; and (c) will improve various electrical and/or thermal properties of the circuit board.

Various objects, features, aspects and advantages of the present invention will become more apparent from the following detailed description of preferred embodiments of the invention, along with the accompanying drawings in which like numerals represent like components.

### BRIEF DESCRIPTION OF THE DRAWINGS

FIG. 1 is a cutaway view of a multi-layer printed wiring board embodying the invention.

FIG. 2 is an exploded view of the printed wiring board of FIG. 1.

FIG. 3 is a cutaway view of a second multi-layer printed wiring board embodying the invention.

### DETAILED DESCRIPTION

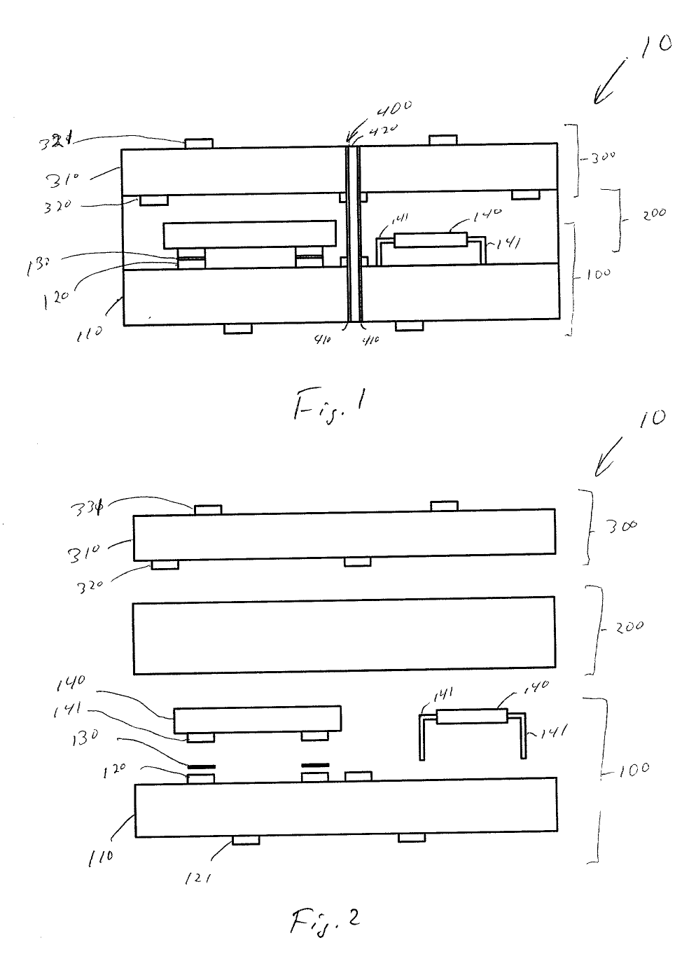

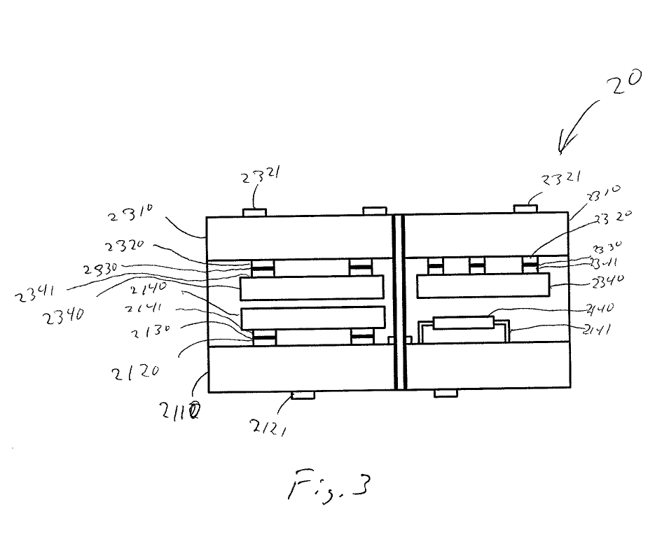

Referring first to FIGS. 1 and 2, multi-layer printed wiring board (PWB) 10 comprises a printed wiring assembly (PWA) 100, a layer of conformal material 200, a double sided PWB 300, and a conductive member 400 electrically coupling PWB 300 to PWA 100. PWA 100 comprises a substrate 110, conductive patterns 120 and 121, a conductive joining material 130, and electronic components 140 including conductive pads or leads 141. PWB 300 comprises substrate layer 310 and conductive pattern layers 320 and 321. Conductive member 400 is a plated and filled through hole having a conductive plating layer 410 on its wall(s) and filler 420 in its center.

The multi-layer PWB 10 of FIG. 1 may be formed by: (a) providing printed wiring assembly 100; (b) encapsulating at least some components 140 of printed wiring assembly 100 in a layer of conformal material 200 to form an inner layer; (c) coupling the PWB 300 to the inner layer 200 by coupling conductive layer/pattern 320 to the inner layer 200 such that the conformal layer 200 is positioned between conductive pattern 320 and the printed wiring assembly 100; (d) forming conductive through hole 400 such that it passes through the layer of conformal material 200 and electrically connects the printed wiring assembly 100 to the at least one additional conductive layer 320.

Referring to FIG. 3, a multi-layer device 20 can be formed by taking printed wiring assemblies (i.e. populated printed wiring boards) and laminating them together via a conformal layer 2200. PWB 20 comprises PWAs 2100 and 2300, and a layer of conformal material 2200, and a conductive member 2400 electrically coupling PWA 2300 to PWA 2100. PWA 2100 comprises a substrate 2110, conductive patterns 2120 and 2121, a conductive joining material 2130, and electronic components 2140 comprising conductive pads or leads 2141. PWA 2300 comprises a substrate 2310, conductive patterns 2320 and 2321, a conductive joining material 2330, and electronic components 2340 comprising conductive pads or leads 2341. Conductive member 2400 is a plated and filled through hole having a conductive plating layer 2410 on its wall(s) and filler 2420 in its center.

The PWAs referred to herein may be formed in any desired manner using any desired material set. The components which are used to populate PWBs to form PWAs may be any type of electrical component, including, among others, the following: packaged or unpackaged integrated circuits; components having leads adapted to electrically couple the component to a PWB; resistors, capacitors, inductors, and transistors. The components may be mounted to the PWBs using any method appropriate to the type of component being mounted. The components may be underfilled prior to encapsulation in conformal layer 200. The components may also be encapsulated in a protective layer prior to being encapsulated within conformal layer 200, or conformal layer 200 may be added in stages to minimize risk to the components of the PWA(s).

Although it is preferred that conformal layer 200 be uncured until after lamination of the first PWA with a PWB or PWA, it is contemplated that in some instances it may be desirable to cure conformal layer 200 and to subsequently process PWA 100 and cured conformal layer 200 as a unit. Such processing may involve lamination, or may involve plating and etching of a conductive pattern on the cured conformal layer.

It should also be appreciated that although PWB's 100, 300, 2110 and 2310 are shown as double-sided PWB's, any or all of them could include many layers of circuitry.

Thus, specific embodiments and applications of forming multi-layer printed wiring boards having circuits embedded within them have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

What is claimed is:

1. A multi-layer printed wiring board comprising:
a first printed wiring assembly including a printed wiring board, and components mounted on a first surface of the printed wiring board, the components and first surface being covered by a layer of conformal material; and
a first conductive pattern which is not part of the first printed wiring assembly, wherein the layer of conformal material is positioned between the first conductive pattern and the first printed wiring assembly.

2. The multi-layer printed wiring board of claim 1 wherein a plated through hole passes through the layer of conformal material and electrically couples at least a portion of the first conductive pattern to the first printed wiring assembly.

3. The multi-layer printed wiring board of claim 1 wherein the first conductive pattern is part of a second printed wiring assembly having components mounted on it, and the conformal layer positioned between the first conductive layer and the first printed wiring assembly encapsulates at least some of the components of each of the first and second printed wiring assemblies.

4. The multi-layer printed wiring board of claim 1 wherein at least one of the encapsulated components is a packaged integrated circuit.

5. The multi-layer printed wiring board of claim 1 wherein at least one of the encapsulated components is an un-packaged integrated circuit.

6. The multi-layer printed wiring board of claim 1 wherein at least one of the encapsulated components comprises leads electrically coupling it to the printed wiring board.

7. A method of forming a multi-layer printed wiring board comprising:
providing a first printed wiring assembly;
encapsulating at least some components of the printed wiring assembly in a layer of conformal material to form an inner layer;
coupling at least one additional conductive layer to the inner layer such that the conformal layer is positioned between the at least one additional conductive layer and the printed wiring assembly.

8. The method of claim 7 further comprising forming a conductive through hole passing through the layer of conformal material, the through hole electrically connecting the first printed wiring assembly to the at least one additional conductive layer.

9. The method of claim 7 wherein the step of coupling the at least one additional conductive layer to the inner layer comprises providing a second printed wiring assembly and laminating the second printed wiring assembly to the first printed wiring assembly via the layer of conformal material such that the layer of conformal material encapsulates at least some components of each of the first and second printed wiring assemblies.
